(19) United States
(12) Patent Application Publication
(10) Pub. No.: US 2006/0267174 A1
(43) Pub. Date: Nov. 30, 2006

(54) Apparatus and method using stackable substrates

(76) Inventors: William Macropoulos, Norfolk, MA (US); Greg Mendolia, Nashua, NH (US); Izzac Khayo, Nashua, NH (US)

Correspondence Address: James S. Finn, 14431 Goliad Dr., Box #8, Malakoff, TX, 75148, US

(21) Appl. No.: 11/349,500

(22) Filed: Feb. 6, 2006

Related U.S. Application Data
(60) Provisional application No. 60/651,529, filed on Feb. 9, 2005.

(51) Int. Cl. H01L 23/02

(52) U.S. Cl. 257/686

(57) ABSTRACT

An embodiment of the present invention provides an apparatus, comprising a plurality of stacked substrates, wherein the substrates are capable of accepting surface mounted components (SMCs) and wherein the plurality of stacked substrates are separated and connected by the surface mounted components (SMC) or solder balls or both.

### CROSS-REFERENCE TO RELATED APPLICATION

This application claims the benefit of priority under 35 U.S.C Section 119 from U.S. Provisional Application Ser. No. 60/651,529, filed Feb. 9, 2005, entitled, “Apparatus Capable of Utilizing Stackable Substrates and Method of Manufacture and Use The.”

### BACKGROUND OF THE INVENTION

Circuit substrate packaging with product size reduction and cost reduction for high volume applications is important. Generally ceramic or FR4 substrates were two metal layers: top and bottom with a dielectric material in between. To reduce size, more metal and dielectric material layers were added to expand on the circuit size with out expanding on the substrate x-y dimensions. In addition, smaller surface mount components were used, which occupied less space.

However, additional layers increase the complexity of interlayer connectivity and overall cost of the circuit. With functionality increases, the number of surface mount components increases and thus the surface area of the circuit increases proportionately. Thus, any combination of existing art tends to increase complexity, drive costs up, and increase module size; specifically in the x and y direction. More importantly, improved line spacing, width, inter-layer connectivity or input/output pad size/pitch within modules does not provide additional room for components. Thus, a strong need in the industry exists for true 3-D structures in order to mount more SMD or RFIC and other ASICS within a smaller footprint.

### SUMMARY OF THE INVENTION

An embodiment of the present invention provides an apparatus, comprising a plurality of stacked substrates, wherein the substrates are capable of accepting surface mounted components (SMCs) and wherein the plurality of stacked substrates may be separated and connected by the surface mounted components (SMC) or solder balls or both. The substrates may be connected and separated by at least three solder balls and the surface mounted components may act as pillars and control solder ball collapse. The plurality of stacked substrates may be capable of being rigid and/or flex substrates and the surface mounted components may be mounted on one or both sides of the stacked substrates.

The stacked substrates may be identical in size or varied in size, shape or composition. Further, the solder balls and or surface mount components may be used to inter connect mechanically and electrically the plurality of substrates. The solder balls or a top portion of the surface mount components may be coated with solder and connected to metal pads located on at least one of the plurality of substrates. The metal layers on each of the plurality of substrates may be connected to each other through vias located on each of the plurality of substrates and may further comprise at least one diagonal through hole located through all of the plurality of substrates to facilitate the lining up of the plurality of substrates. An embodiment of the present invention thus provides that the stacking of the plurality of substrates allows for simple and direct access to components for purposes of tuning circuits, either on the individual boards before they are stacked (sub-assemblies) or in final configuration once they have been stacked.

Yet another embodiment of the present invention provides a method, comprising stacking a plurality of substrates by separating and connecting the plurality of stacked substrates by surface mounted components (SMC) or solder balls or both. The substrates may be connected and separated by at least three solder balls and wherein the surface mounted components may act as pillars and control solder ball collapse. An embodiment of the present invention provides the present method may further comprise using the solder balls and or surface mount components to inter connect mechanically and electrically the plurality of substrates and may further comprise connecting metal layers on each of the plurality of substrates to each other through vias located on each of the plurality of substrates.

Yet another embodiment of the present invention provides an integrated circuit, comprising a plurality of stacked substrates, wherein the substrates are capable of accepting surface mounted components (SMCs) and wherein the plurality of stacked substrates may be separated and connected by the surface mounted components (SMC) or solder balls or both. The substrates of the present integrated circuit may be connected and separated by at least three solder balls and the surface mounted components may act as pillars and control solder ball collapse. The solder balls and or surface mount components may be used to inter connect mechanically and electrically the plurality of substrates and metal layers may be placed on each of the plurality of substrates connected to each other through vias located on each of the plurality of substrates.

### BRIEF DESCRIPTION OF THE DRAWINGS

The present invention is described with reference to the accompanying drawings. In the drawings, like reference numbers indicate identical or functionally similar elements. Additionally, the left-most digit(s) of a reference number identifies the drawing in which the reference number first appears.

FIG. 1 illustrates stacked substrates of one embodiment of the present invention;

FIG. 2 illustrates a stacked single substrate of one embodiment of the present invention;

FIG. 3 illustrates compressed stacked substrates of one embodiment of the present invention;

FIG. 4 pictorially shows a top view of the lower substrate of an embodiment of the present invention;

FIG. 5 is a side pictorial representation of the stacked substrates of an embodiment of the present invention;

FIG. 6 is an exploded pictorial representation depicting the use of surface mounting devices that may be used to connect and separate substrates in an embodiment of the present invention; and

FIG. 7 depicts a multilayer strip with arrays and multiple modules in each array of an embodiment of the present invention.

### DESCRIPTION OF THE PREFERRED EMBODIMENT

One embodiment of the present invention provides stacking a plurality of rigid and/or flex substrates, each with components mounted on one or both sides of the individual boards. These stacked substrates may be identical in size or vary in size, shape or composition. In an embodiment of the present invention, modules used in mobile phones may use two substrates stacked on top of each other, however it is understood that there is no theoretical limit to the number of substrates that may be stacked. Substrate stacking allows multiple substrates to be attached in the Z direction and thus reduce the need for valuable space in the x and y direction on the motherboard.

In an embodiment of the present invention, a multilayer strip with 3 arrays and multiple modules in each array may be utilized—although the present invention is not limited in this respect. Each module in the array may be populated with surface mount components, which may be used in place of, or in addition to the solder balls for connection to and separation from the plurality of substrates.

In the event of large or multiple (two or more) substrate stacking, the surface mount components may act as pillars and to control solder bal collapse. After population of the strip with surface mounted devices (SMDs) and solder reflow, die attaching and wire bonding of Semiconductor chips, solder ball placement and reflow may define the substrate stacking.

Solder balls and or surface mount components may be used to inter connect mechanically and electrically multiple substrates. While in the populated strip configuration, the solder ball or the top portion of the surface mount components may be coated with solder and connect to metal pads located on the bottom side of a separate substrate, which may be individually picked and placed or as another inverted entire strip. A fixture may be used to help in the aligning process for the top to the bottom substrate.

One end of a 50 ohm line of top substrate (#1) may connected through a via to a metal pad on bottom side of substrate #1 (it is understood that any particular values are for illustrative purposes only and should not be considered to limit the present invention). The top metal layer of substrate #2 may also be a 50 ohm line. On each end of the line, one side of surface mount capacitors may be soldered. To maintain stability and flatness of the substrates, additional surface mount components may be soldered on metal pads located on the sides of substrate #2 which may run in parallel direction to the 50 ohm line.

Solder ball pads to accept solder balls may also be provided on top layer of substrate #2 and the bottom layer of substrate #1. Further, diagonal through holes on both substrates will help towards alignment of substrate #1 and substrate #2 using a jig for the reflow of solder balls and or the solder coated terminations of the surface mount components. When reflowed, the 50 ohm line on substrate #1 will be mechanically and electrically connected to the 50 ohm line on substrate #2. If desired, the stacked substrates may then be attached to a test board for evaluation. To facilitate evaluation of the present invention, the structure may be under filled with glob top epoxy, temperature cycled and retested

If individual/cingulated substrates are picked and placed on the strip and reflowed, standard molding will under fill and over mold the stacked substrates on the strip. The strip then may be sawed and cingulated into a 3D stacked module structure. If two strips are connected together as described earlier, strategically located openings in the strip format will help to under fill between the substrates and over the strip.

Although not limited to any particular interconnect options, examples include solder balls, 0402s etc. To provide for a larger gap between a plurality of substrates, larger size surface mount components may be used.

Embodiments of the present invention provide many benefits to the current state of the art, including:

a. It is an enabling Miniaturization technology using standard and multilayer and multi dimensional substrates;

b. It allows for single side and double side circuit population with flip chip or wire bonded die and may include the attachment of surface mount components in a LGA technology;

c. It can use BGA or the surface mount components as the means of vertically interconnecting multiple substrates;

d. It allows for trouble shooting and fine tuning of each individual substrate during the engineering and product development phases;

e. It allows for the integration/stacking of multiple thicknesses and metal layers of substrate materials;

f. As tuning up of circuits is commonly required for products under development, this type of 3D structure is the only one that allows for simple and direct access to components for purposes of tuning (changing value or position) circuits, either on the individual boards before they are stacked (sub-assemblies) or in final configuration once they have been stacked;

g. It allows for the stackable integration of other known good fully molded packages or LGA, BGA, μBGA packages;

If there is an issue of stacking two rigid circuit boards like BT, FR4 or ceramic/LTCC, one or both of the stacked boards can be made of flex materials. This is typically a more costly material, but it offers better feature resolution (conductive traces, vias, and spacings), and is compliant in the event there are issues with flatness/planarity when stacking, or if three is a need for more flexibility in the material to survive temperature cycle/shock (the dissimilar materials between the boards and plastic encapsulate over-mold may have large enough differences in temperature coefficient of expansion (TCE) that it may de-laminate over temp.)

An embodiment of the present invention addresses the creation of more surface area to mount components. Traditional circuits for Multi-Chip-Modules (MCMs) mount components all on one side, so there is a 1 to 1 ratio between area for components and area the chip consumes when mounted in a customer's product (eg mobile phone mother board). And the ratio is typically actually less than one since the top layer is often partially used to route lines. An embodiment of the present invention provides the components our capable of being mounted on the top of both boards, for a 2× improvement in area available for components within our MCM without growing the area of the MCM itself. Further, it is even possible to mount components on 3 or all 4 sides of the boards giving as much as 4× improvement for 2 stacked boards in a 3D package—although the present invention is not limited in this respect. More than 2 substrates may be stacked if desired for specific applications.

An embodiment of the present invention leverages mature high volume processes and manufacturing infrastructure already in place globally. This reduces risk and cost, and enables simplified paths to second-sourcing, often requested by customers to lower supply chain risks. All components and lines printed on the top surface of the top stacked board can easily be “tuned” to adjust circuit performance and facilitating quicker product development. In order to do this, no plastic overmold is used during engineering development, allowing max flexibility and access during development, but very representative RF-wise of how it will behave when fully assembled with overmold (since the dielectric constant of the overmold is so low). Z-axis interconnects between the boards may be accomplished by using:

1) conventional 0201 (or other size like 0402 or 01005 SMD components)—some could be components already needed by the circuit, thus being “free” in terms of space and cost. SMDs may be conductive on all four sides of both terminations, so the solder will easily wet on both boards to form a z-axis interconnect;

2) solder balls on one (or both) boards, with the other board having a land grid array (LGA to marry up to the balls;

3) custom component in at least 3 locations (to make a 3-legged table) with multiple connections in the z-axis. This can be as simple as a very small (˜0.5×0.5 mm) board (rigid or flex) with 4 pads on the top, 4 on the bottom, and 4 via holes connecting the pads in the z-direction. For cost savings, the vias may be placed in the streets so that when the boards are cut and cingulated, the vias/pads create castillations for better soldering, smaller size, and lower cost (½ as many vias may thus be needed to make the same number of I/Os).

Traditional boards/packaging have to compromise on thickness and dielectric constants. Thin boards are wanted because they are better thermally and smaller height is desired as well as better RF grounding of some RF components. Thick boards are desired to create higher impedance inductors and transmission lines. Low dielectric is wanted for the same reason (high impedance). High dielectric is desired for more sensitive parts of the circuit where coupling is of concern, or you want to print capacitors. With the stacked 3D approach of the present invention, it is possible to mix and match the best of both worlds to eliminate these compromises. Although not limited to this, for example, two high dielectric boards may be used, that are very thin, with a reasonably thick (˜0.6 mm) air gap are provided in an embodiment of the present invention. Sensitive low impedance parts and parts needing good RF or thermal ground may be be placed on the lower substrate. Components, transmission lines and inductors wanting to see high impedance may be, although is not required to be, placed on the upper substrate. Even though the upper substrate may be high dielectric, due to the air gap between these components and ground (typically bottom of the 3D package, but ground can be brought to any of the 4 metal levels), the effective dielectric of the entire sandwiched structure may be low.

The top substrate does not have to be the exact same size or shape of the lower board, so if 1½ boards are needed to fit all the components, or you want access to some of the lower components, a smaller upper board may be used.

A conventional package may have a 4-layer BT substrate with blind and buried vias; however, in an embodiment of the present invention using the 3D package approach, it is possible to have the exact same amount of metal layers without compromise, but would use two 2-layer BT substrates with just through hole vias which are much less expensive, potentially saving more than the additional z-access interconnect and process costs, giving a net savings in manufacturing.

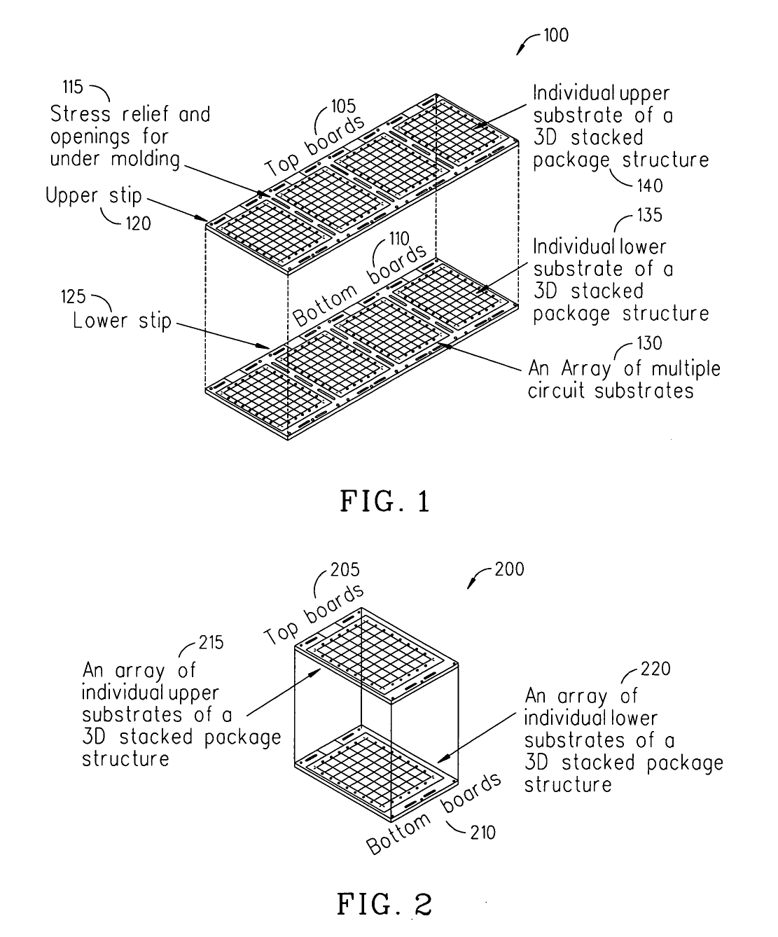

Turning now to the figures, FIG. 1, shown generally as 100, provides a stacked substrates of one embodiment of the present invention. Top board 105 is shown distanced from bottom board 110 and using vision, fiducials and or fixcturing, hybrid circuits can be stacked on top of one another utilizing Ball Grid Arrays (BGAs), or Surface Mount Devices (SMDs) as stand offs for electrical and mechanical connectivity to create a 3D package structure. Top board 105 may include individual upper substrate 140 and stress relief and openings for under molding 115 as well us upper stip 120. Bottom boards 110 may include individual lower substrate 135 and an array of multiple circuit substrates 130 and lower stip 125. Openings in the substrate will enable molding over and between the circuit structures FIG. 2 at 200, illustrates a stacked single substrate of one embodiment of the present invention. Top board 205 include an array of individual upper substrates of a 3d stacked page structure 215 and bottom board 210 include an array of individual lower substrates of a 3d stacked page structure 220.

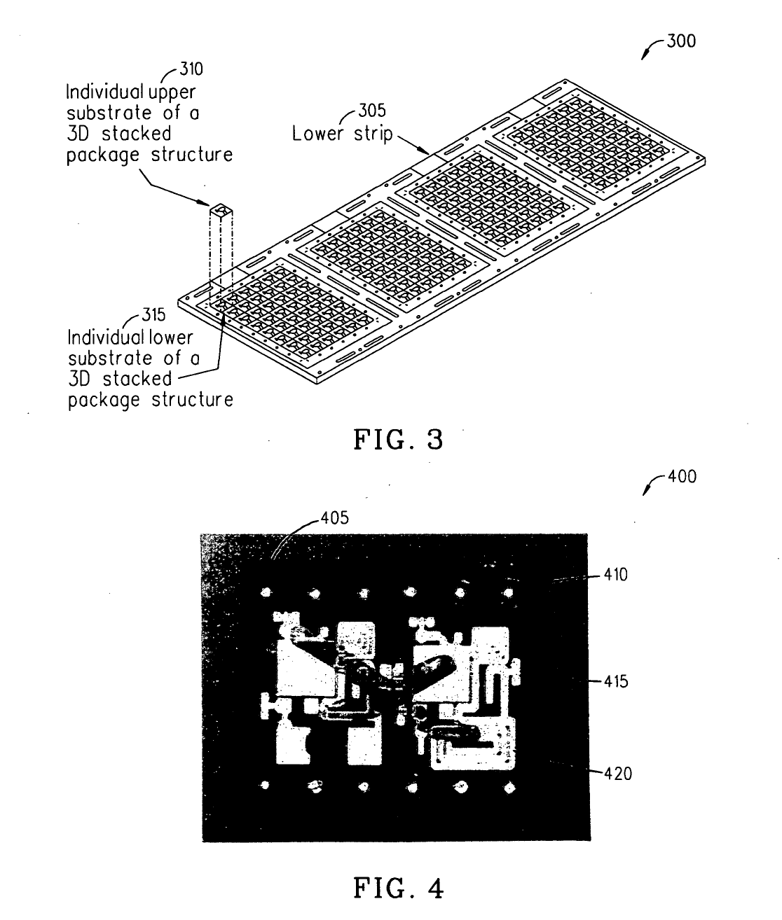

FIG. 3 at 300 is shown individual upper substrate of a 3D stacking package structure 310 and individual lower susbstrate of a 3D stacked package structure 315 compressed together. Lower stip is shown at 305.

FIG. 4, shown generally as 400, pictorially shows a top view of the lower substrate 405 of an embodiment of the present invention. Circuitry 420, solder balls 410 and connecting vias 415 are shown on substrate 405.

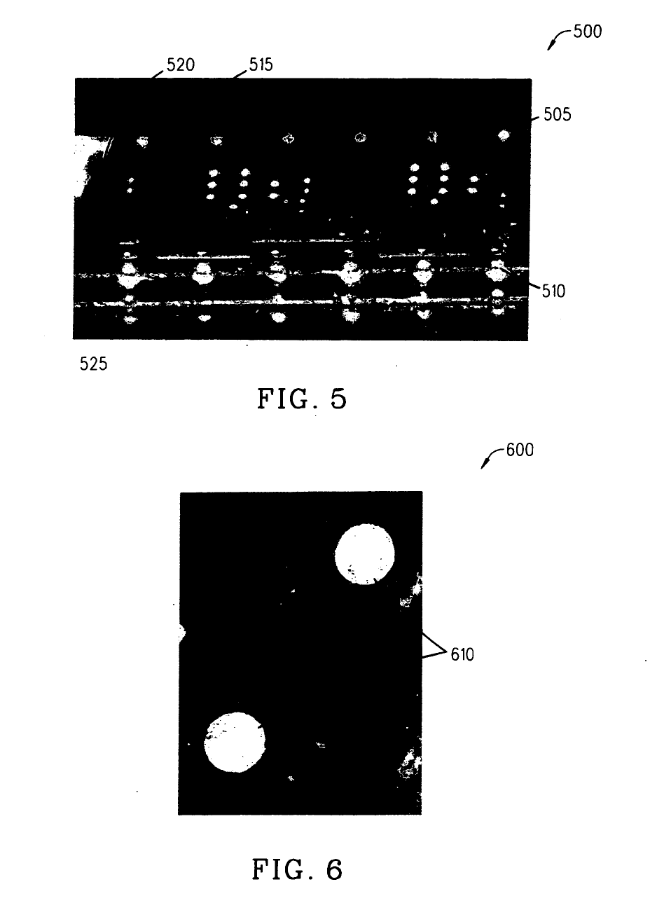

FIG. 5 at 500 is a side pictorial representation of the stacked substrates of an embodiment of the present invention. Solder balls (two of which are represented as 505 and 510) connect and separate top substrate 520 and lower substrate 525. Metal layer 515 is shown on top substrate 520.

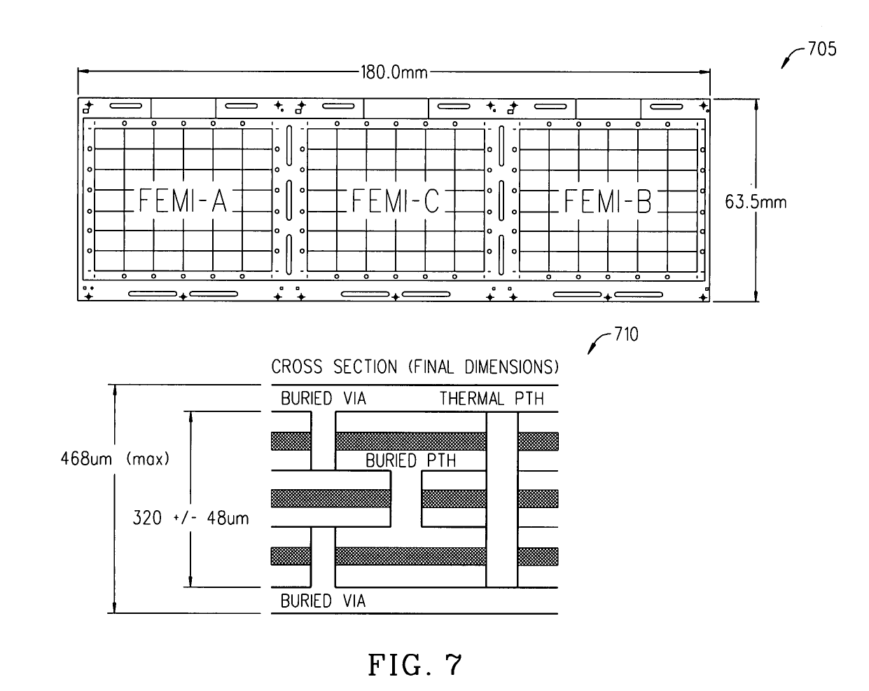

FIG. 6 at 600 is an expanded view depicting the use of surface mounting devices 610 that may be used to connect and separate substrates in an embodiment of the present invention. FIG. 7, at 700, depicts a multilayer strip 705 with 3 arrays and multiple modules in each array. A cross section of the multilayer strip 705 is shown at 710.

While the present invention has been described in terms of what are at present believed to be its preferred embodiments, those skilled in the art will recognize that various modifications to the disclose embodiments can be made without departing from the scope of the invention as defined by the following claims. Further, although a specific scanning antenna utilizing dielectric material is being described in the preferred embodiment, it is understood that any scanning antenna can be used with any type of reader any type of tag and not fall outside of the scope of the present invention.

What is claimed is:

1. A apparatus, comprising:
a plurality of stacked substrates, wherein said substrates are capable of accepting surface mounted components (SMCs) and wherein said plurality of stacked substrates are separated and connected by said surface mounted components (SMC) or solder balls or both.

2. The apparatus of claim 1, wherein said substrates are connected and separated by at least three solder balls and wherein said surface mounted components act as pillars and control solder ball collapse.

3. The apparatus of claim 1, wherein said plurality of stacked substrates are capable of being rigid and/or flex substrates and wherein capable of said surface mounted components being mounted on one or both sides of said stacked substrates.

4. The apparatus of claim 1, wherein said stacked substrates are capable of being of being identical in size or varied in size, shape or composition.

5. The apparatus of claim 1, wherein said solder balls and or surface mount components are used to inter connect mechanically and electrically said plurality of substrates.

6. The apparatus of claim 5, wherein said solder balls or a top portion of said surface mount components are coated with solder and connect to metal pads located on at least one of said plurality of substrates.

7. The apparatus of claim 1, further comprising metal layers on each of said plurality of substrates connected to each other through vias located on each of said plurality of substrates.

8. The apparatus of claim 1, further comprising at least one diagonal through hole located through all of said plurality of substrates to facilitate the lining up of said plurality of substrates.

9. The apparatus of claim 1, wherein the stacking of said plurality of substrates allows for simple and direct access to components for purposes of tuning circuits, either on the individual boards before they are stacked (sub-assemblies) or in final configuration once they have been stacked.

10. A method, comprising:
stacking a plurality of substrates by separating and connecting said plurality of stacked substrates by surface mounted components (SMC) or solder balls or both.

11. The method of claim 10, wherein said substrates are connected and separated by at least three solder balls and wherein said surface mounted components act as pillars and control solder ball collapse.

12. The method of claim 10, further comprising using rigid and/or flex substrates and surface mounting components on one or both sides of said stacked substrates.

13. The method of claim 10, further comprising using stacked substrates that are varied in size, shape or composition.

14. The method of claim 10, further comprising using said solder balls and or surface mount components to inter connect mechanically and electrically said plurality of substrates.

15. The apparatus of claim 14, further comprising coating said solder balls or a top portion of said surface mount components and connecting them to metal pads located on at least one of said plurality of substrates.

16. The method of claim 10, further comprising connecting metal layers on each of said plurality of to each other through vias located on each of said plurality of substrates.

17. The method of claim 10, further comprising placing at least one diagonal through hole through all of said plurality of substrates to facilitate the lining up of said plurality of substrates.

18. An integrated circuit, comprising:
a plurality of stacked substrates, wherein said substrates are capable of accepting surface mounted components (SMCs) and wherein said plurality of stacked substrates are separated and connected by said surface mounted components (SMC) or solder balls or both.

19. The integrated circuit of claim 18, wherein said substrates are connected and separated by at least three solder balls and wherein said surface mounted components act as pillars and control solder ball collapse.

20. The integrated circuit of claim 18, wherein said solder balls and or surface mount components are used to inter connect mechanically and electrically said plurality of substrates.

21. The integrated circuit of claim 18, further comprising metal layers on each of said plurality of substrates connected to each other through vias located on each of said plurality of substrates.
